(19) United States
(12) Patent Application Publication
(10) Pub. No.: US 2015/0366081 A1
(43) Pub. Date: Dec. 17, 2015

(54) MANUFACTURING METHOD FOR CIRCUIT STRUCTURE EMBEDDED WITH ELECTRONIC DEVICE

(71) Applicant: Unimicron Technology Corp., Taoyuan (TW)

(72) Inventor: I-Ta Tsai, Kaohsiung City (TW)

(21) Appl. No.: 14/304,979

(22) Filed: Jun. 15, 2014

(51) Int. Cl. H05K 3/46; H05K 3/42; H05K 3/30

(52) U.S. Cl. CPC H05K 3/4655; H05K 3/30; H05K 3/421; H05K 3/429

(57) ABSTRACT

A manufacturing method for a circuit structure embedded with an electronic device including the following steps is provided. A first dielectric material is provided. At least one electronic device is disposed on the first dielectric material. A second dielectric material is laminated on the first dielectric material, and two conductive materials are disposed on the first dielectric material and the second dielectric material respectively, such that the electronic device is embedded between the first dielectric material and the second dielectric material, wherein the first dielectric material and the second dielectric material are respectively located between the electronic device and the corresponding conductive material, and the first dielectric material, the second dielectric material, the electronic device and the two conductive materials form a core board. An inner-layer circuit is formed on the core board, and the inner-layer circuit is connected with the electronic device.

### BACKGROUND OF THE INVENTION

1. Field of the Invention

The invention relates to a circuit structure, and particularly relates to a circuit structure embedded with an electronic device.

2. Description of Related Art

In recent year, in order to enhance the application of the printed circuit board (PCB), the printed circuit board has been produced into multi-layer circuit structure in present technology. The manufacturing method of multi-layer circuit structure is to repeatedly laminate the copper foil and the prepreg on the core board, and to fill the conductive materials inside the blind hole by the electroplating process for interconnecting each layer. In addition, lots of electronic devices, such as passive electronic devices, are capable to be embedded inside the multi-layer circuit structure according to the requirement.

Conventionally, the manufacturing method for electronic device embedded in the circuit board, a cavity for housing the electronic device is formed on the core board by laser processing or mechanical drilling before build-up process. In order to make the electronic device to be put inside the cavity mentioned-above, an adhesive or other materials are disposed on one side of the cavity in advance to enclose the cavity. Therefore, the electronic device may be disposed inside the cavity. Next, the electronic device is capable to be embedded and fixed inside the core board after the prepreg is laminated on the core board, and the adhesive may be removed after the electronic device is fixed inside the core board. After the electronic device is embedded inside the core board by the mentioned-above method, more build-up structures formed by the copper foils and the prepregs may be continuously laminated on the core board, so as to finish the multi-layer circuits structure embedded with the electronic device. However, the processing step mentioned above is complicated, for example, the cavity is disposed on the core board by additional processing steps, and the consumptive materials (such as the adhesive tape) need to be used as assist during the step of disposing the electronic device inside the cavity, which makes the manufacturing method generate higher cost in manufacturing.

### SUMMARY OF THE INVENTION

The invention provides a manufacturing method for circuit structure embedded with the electronic device, which has simplified process and reduces the manufacturing cost.

A manufacturing method for circuit structure embedded with the electronic device of the invention comprises: providing a first dielectric material; disposing at least one electronic device on the first dielectric material; laminating a second dielectric material on the first dielectric material, and disposing two conductive materials on the first dielectric material and the second dielectric material respectively, such that the electronic device is embedded between the first dielectric material and the second dielectric material, wherein the first dielectric material and the second dielectric material are respectively located between the electronic device and the corresponding conductive materials, and the first dielectric material, the second dielectric material, the electronic device and the two conductive materials form a core board; forming an inner-layer circuit on the core board, and the inner-layer circuit is connected to the electronic device.

In an embodiment of the invention, in the step of providing the first dielectric material, the first dielectric material is disposed on a bearing plate, and a release layer is disposed between the first dielectric material and the bearing plate. After the step of disposing the electronic device on the first dielectric material, the release layer and the bearing plate are removed from the first dielectric material.

In an embodiment of the invention, the manufacturing method for circuit structure embedded with electronic device further comprises: before the step of disposing the electronic device on the first dielectric material, forming a plurality of alignment target holes on the first dielectric material.

In an embodiment of the invention, the manufacturing method for circuit structure embedded with electronic device further comprises: before the step of disposing the electronic device on the first dielectric material, disposing at least one thermal curing glue on the first dielectric material.

In an embodiment of the invention, in the step of disposing the electronic device on the first dielectric material, the electronic device is disposed on the thermal curing glue, and the thermal curing glue is cured by a baking process, such that the electronic device is fixed on the first dielectric material.

In an embodiment of the invention, the step of forming the inner-layer circuit on the core board further comprises: forming at least one blind hole on the second dielectric material, and the blind hole is connected to the electronic device; etching the two conductive materials and forming a conductive layer inside the blind hole, such that two inner-layer circuit patterns are formed by the two conductive materials, and the conductive layer is connected to the inner-layer circuit pattern located on the second dielectric material and the electronic device by the blind hole, and the two inner-layer circuit patterns and the conductive layer are formed the inner-layer circuit.

In an embodiment of the invention, the step of forming the blind hole comprises laser process, the step of etching the two conductive materials comprises lithography process, and the step of forming the conductive layer inside the blind hole comprises an electroplating process.

In an embodiment of the invention, the manufacturing method for circuit structure embedded with electronic device further comprises: forming at least one dielectric layer and at least one build-up circuit on the core board, wherein the dielectric layer is located between the build-up circuit and the inner-layer circuit, and the build-up circuit is connected with the inner-layer circuit.

In an embodiment of the invention, the manufacturing method for circuit structure embedded with electronic device further comprises processing a surface treatment to the build-up circuit.

In an embodiment of the invention, the first dielectric material and the second dielectric material comprise a prepreg doping with a glass fiber, and the two conductive materials comprises copper foil.

To sum up, in the manufacturing method for circuit structure embedded with electronic device of the invention, the electronic device is disposed on the first dielectric material, and the second dielectric material is laminated on the first dielectric material, such that the electronic device is embedded between the first dielectric material and the second dielectric material, and the conductive materials are disposed on the first dielectric material and the second dielectric material, so as to form the core board. Therefore, the electronic device is embedded inside the core board in the manufacturing process of the core board, which reduces the processing steps and the related consumptive materials what the cavity formed on the core board needed in the related art. In view of this, the manufacturing method for circuit structure embedded with the electronic device of the invention not only features in simplified process, but also reduces manufacturing cost.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1. is a flow chart of manufacturing method for circuit structure embedded with electronic device according to an embodiment of the invention.

FIG. 2A. to FIG. 2J are schematic views of process flow for circuit structure embedded with electronic device in FIG. 1.

### DESCRIPTION OF THE EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

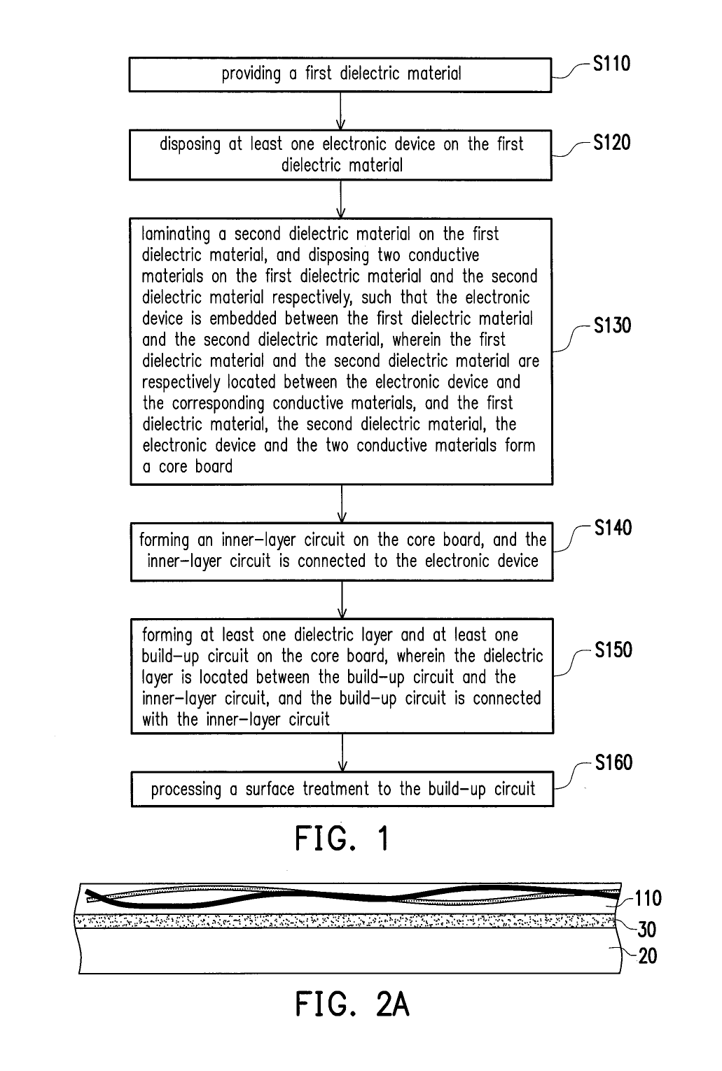

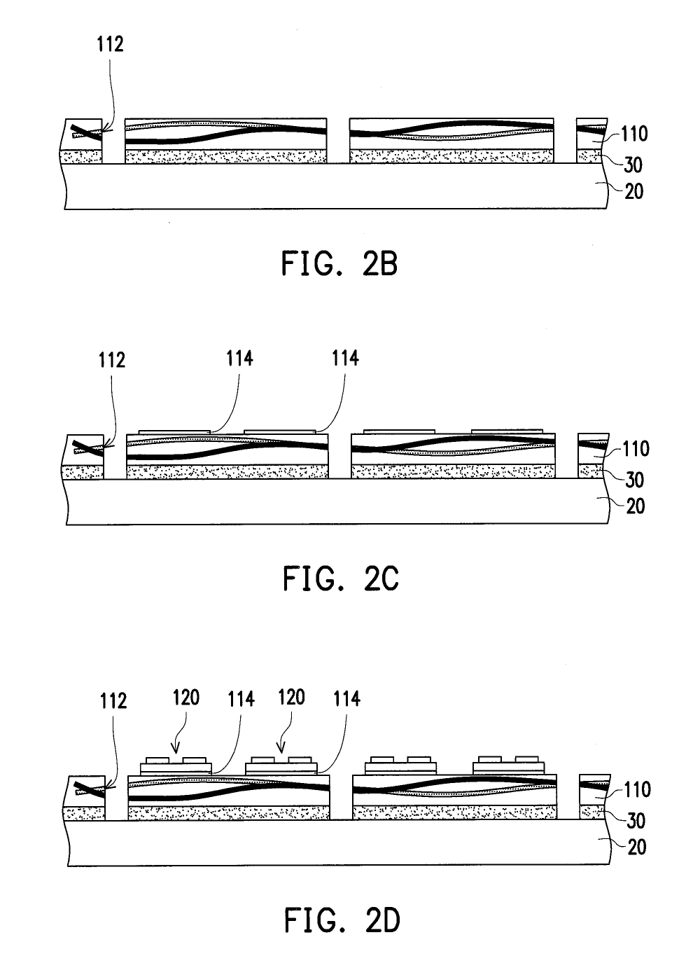

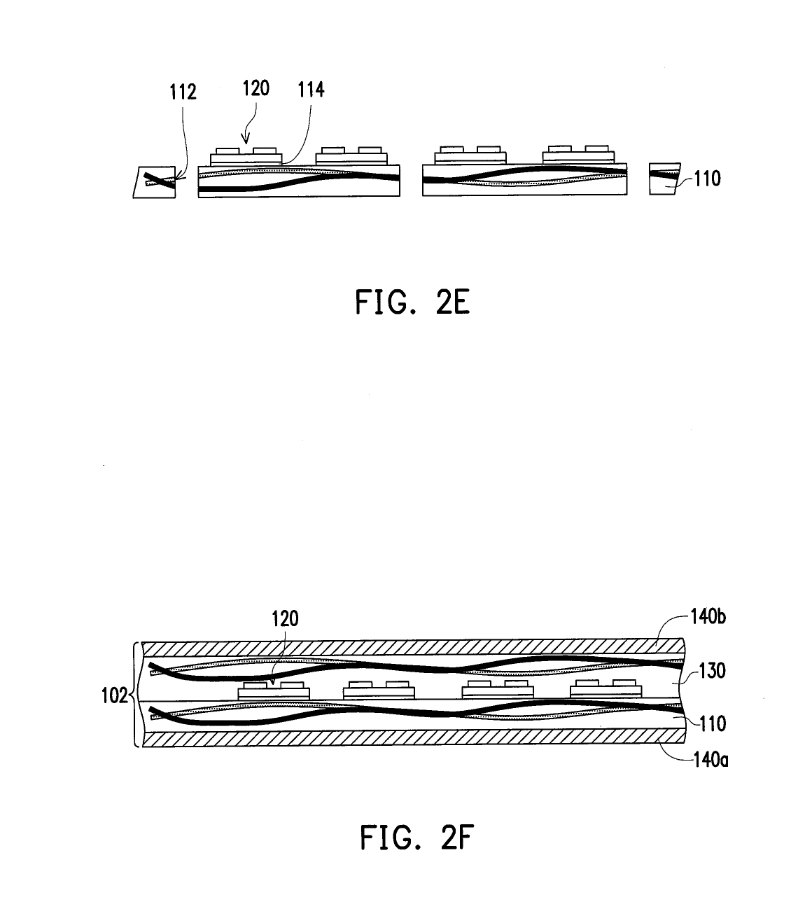

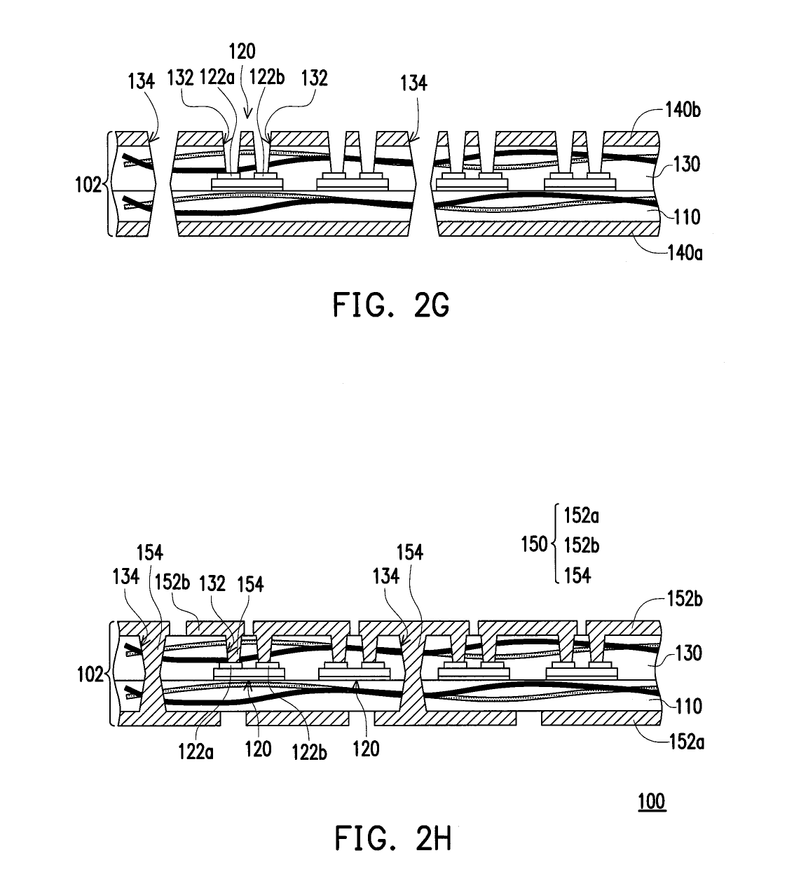

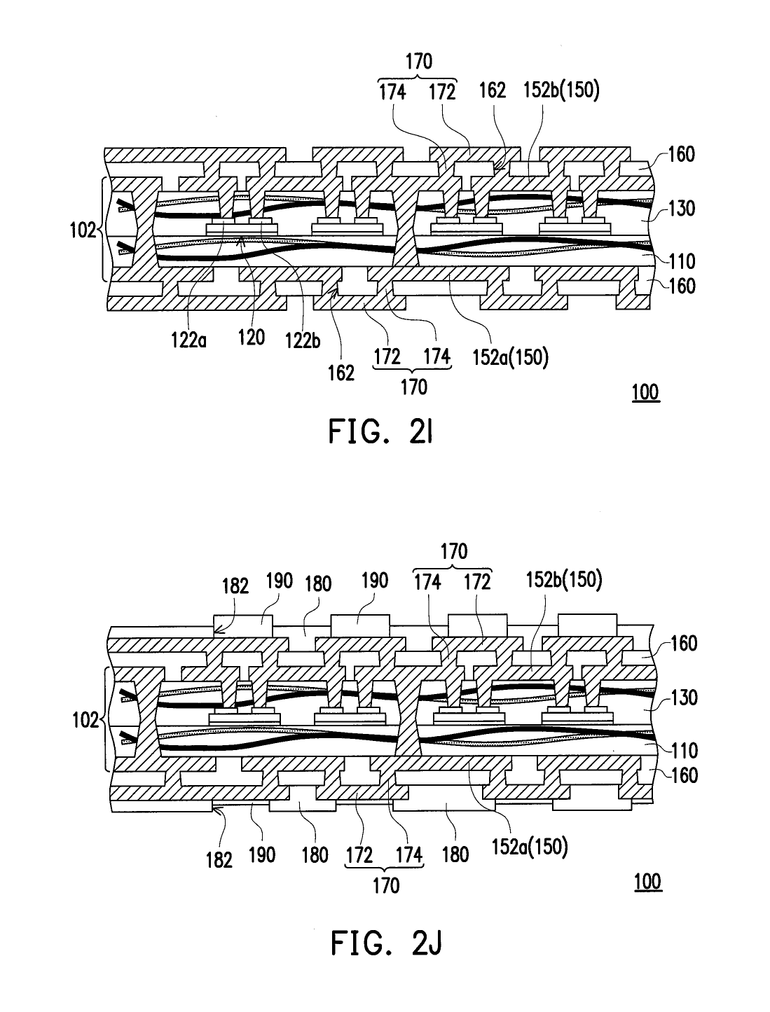

FIG. 1. is a flow chart of manufacturing method for circuit structure embedded with electronic device according to an embodiment of the invention. FIG. 2A. to FIG. 2J are schematic views of process flow for circuit structure embedded with electronic device in FIG. 1. Please refer to FIG. 1 and FIG. 2A to FIG. 2J, in this embodiment, the manufacturing method for circuit structure embedded with electronic device comprises the following steps. In the step S110, providing a first dielectric material 110. In the step S120, disposing at least one electronic device 120 on the first dielectric material 110. In the step S130, laminating a second dielectric material 130 on the first dielectric material 110, and disposing two conductive materials 140a, 140b on the first dielectric material 110 and the second dielectric material 130 respectively, such that the electronic device 120 is embedded between the first dielectric material 110 and the second dielectric material 130, wherein the first dielectric material 110 and the second dielectric material 130 are respectively located between the electronic device 120 and the corresponding conductive materials 140a,140b, and the first dielectric material 110, the second dielectric material 130, the electronic device 120 and the two conductive materials 140a, 140b form a core board 102. In the step S140, forming an inner-layer circuit 150 on the core board 102, and the inner-layer circuit 150 is connected to the electronic device 120. In the step S150, forming at least one dielectric layer 160 and at least one build-up circuit 170 on the core board 102, wherein the dielectric layer 160 is located between the build-up circuit 170 and the inner-layer circuit 150, and the build-up circuit 170 is connected with the inner-layer circuit 150. In the step of S160, processing a surface treatment to the build-up circuit 170. The following section is orderly explained the manufacturing method for circuit structure embedded with electronic device in this embodiment with the FIG. 2A to FIG. 2J.

Firstly, in the step of S110, providing a first dielectric material 110. Please refer to FIG. 1. and FIG. 2A, in this embodiment, in the step of providing the first dielectric material 110, the first dielectric material 110 is disposed on a bearing plate 20, and a release layer 30 is disposed between the first dielectric material 110 and the bearing plate 20. The first dielectric material 110 in this embodiment is, for example, a prepreg doping with glass fiber, allowing the first dielectric material 110 has good intensity, but the first dielectric material 110 is not limited thereto in the invention. In addition, the first dielectric material 110 is disposed on the bearing plate 20 with good intensity, which accelerates the following processing to the first dielectric material 110, for example, disposing a blind hole or glue on the first dielectric material 110 (set as below). Furthermore, a release layer 30 is disposed between the first dielectric material 110 and the bearing plate 20, which is helpful to separate the first dielectric material 110 and the bearing plate 20 after the first dielectric material 110 is processed. However, whether the release layer 30 and the bearing plate 20 are disposed or not is not limited in the invention, it can be selected according to actual requirement.

Next, in the step of S120, disposing at least one electronic device 120 on the first dielectric material 110. Please refer to FIG. 1 and FIG. 2B, in this embodiment, before the step of disposing the electronic device 120 on the first dielectric material 110, further comprises forming a plurality of alignment target holes 112 on the first dielectric material 110. The alignment target holes 112 are formed on the first dielectric material 110 by the laser process, and penetrate the first dielectric material 110 and the release layer 30, but the formation of the alignment target holes 112 is not limited in the invention, it can be selected according to actual requirement. The alignment target holes 112 may define an area where is predetermined to dispose the electronic device 120 on the first dielectric material 110. For example, the alignment target holes 112 may be disposed on the periphery of the area where is predetermined to dispose the electronic device 120 on first dielectric material 110, and in the following steps of disposing the electronic device 120, the location of the electronic device 120 on the first dielectric material 110 may be adjusted according to the location of the alignment target holes 112.

Then, please refer to FIG. 1 and FIG. 2C, in this embodiment, before the step of disposing the electronic device 120 on the first dielectric material 110, further comprises disposing at least one thermal curing glue 114 on the first dielectric material 110. The thermal curing glue 114 is formed on the first dielectric material 110 by the spray process, but the formation of the thermal curing glue 114 is not limited in the invention, it can be selected according to actual requirement. In the step of disposing the thermal curing glue 114, the thermal curing glue 114 may be disposed on the predetermined area of the first dielectric material 110 according to the location of the alignment target holes 112, for example, the thermal curing glue 114 is disposed on the area between the alignment target holes 112 on the predetermined area of the first dielectric material 110, such that the electronic device 120 is disposed on the predetermined area on first dielectric material 110 by the thermal curing glue 114.

Next, please refer to FIG. 1 and FIG. 2D, in this embodiment, in the step of disposing the electronic device 120 on the first dielectric material 110, the electronic device 120 is disposed on the thermal curing glue 114. Specifically, the electronic device 120 in this embodiment is illustrated by four, but the number of the electronic device 120 may be adjusted according to the actual requirement, while the number and the location of the thermal curing glue 114 correspond to those of the electronic device 120. In addition, the electronic device 120 may adopt thin and passive electronic device, for example, it is a Si-base thin film capacitor with 35 μm (micrometer) in thickness, but it is not limited in the invention. Because the alignment target holes 112 is formed on the first dielectric material 110 before disposing the electronic device 120 on the first dielectric material 110, and the thermal curing glue 114 is disposed on the predetermined area of the first dielectric material 110 according to the location of the alignment target holes 112, therefore, in the step of disposing the electronic device 120 on the first dielectric material 110, the electronic device 120 is disposed on the predetermined area of the first dielectric material 110 by the corresponding thermal curing glue 114 according to the location of the alignment target holes 112. After the electronic device 120 is disposed on the thermal curing glue 114, the thermal curing glue 114 is cured by the baking process, such that the electronic device 120 is fixed on the first dielectric material 110. Herein, the material having short time in cured may be selected to be the thermal curing glue 114. Therefore, the thermal curing glue 114 is cured only by short-time baking, and the temperature and time in baking the thermal curing glue 114 does not make the first dielectric material 110 varied (for example, melting by heat). The electronic device 120 is fixed on the first dielectric material 110 by the thermal curing glue 114. However, in other embodiments, the electronic device 120 is capable to be directly disposed on the first dielectric material 110, or disposed on the first dielectric material 110 by other kinds of glues, whether the thermal curing glue 114 disposed or not, and the disposition of the electronic device 120 are not limited in the invention.

Next, please refer to FIG. 1. and FIG. 2E, in this embodiment, because the first dielectric material 110 is disposed on the bearing plate 20 and the release layer 30, thus after the step of disposing the electronic device 120 on the first dielectric material 110, the release layer 30 and the bearing plate 20 are removed from the first dielectric material 110. Because the release layer 30 is disposed between the first dielectric material 110 and the bearing plate 20, thus the bearing plate 20 and the release layer 30 are easily removed from the first dielectric material 110. However, in the embodiment without the bearing plate 20 and the release layer 30, the step of removing the bearing plate 20 and the release layer 30 may be omitted.

Next, in the step S130, laminating a second dielectric material 130 on the first dielectric material 110, and disposing two conductive materials 140a, 140b on the first dielectric material 110 and the second dielectric material 130 respectively, such that the electronic device 120 is embedded between the first dielectric material 110 and the second dielectric material 130, wherein the first dielectric material 110 and the second dielectric material 130 are respectively located between the electronic device 120 and the conductive materials 140a, 140b, and the first dielectric material 110, the second dielectric material 130, the electronic device 120 and the two conductive materials 140a, 140b form a core board 102. Please refer to FIG. 1 and FIG. 2F, in this embodiment, the second dielectric material 130 is laminated on the first dielectric material 110, wherein the second dielectric material 130 is, for example, a prepreg doping with glass fiber, allowing the second dielectric material 130 has good intensity, but the second dielectric material 130 is not limited thereto in the invention. After laminating the second dielectric material 130 on first dielectric material 110, the prepreg of the second dielectric material 130 covers the electronic device 120, and fills into the alignment target holes 112 of the first dielectric material 110. Therefore, the electronic device 120 is embedded between the first dielectric material 110 and the second dielectric material 130. Because the electronic device 120 in this embodiment is thin and passive electronic device, thus the thin electronic device 120 may easily be covered with the first dielectric material 110 and the second dielectric material 130. In addition, the two conductive materials 140a, 140b is, for example, the copper foil or other appropriate conductive materials, which is not limited in the invention. In this step, the two conductive materials 140a, 140b are disposed on the outer surfaces of the first dielectric material 110 and the second dielectric material 130 respectively, wherein the second dielectric material 130 and the conductive material 140b disposed on the second dielectric material 130 may be disposed on the first dielectric material 110 and the electronic device 120 by different process, and also adapted to be produced as a composited plate in advance and laminating on the first dielectric material 110 and the electronic device 120 by the same process. So far, the first dielectric material 110, the second dielectric material 130, the electronic device 120 and the two conductive materials 140a, 140b form a core board 102, and the electronic device 120 is embedded in the core board 102.

Next, in the step S140, forming the inner-layer circuit 150 on the core board 102, and the inner-layer circuit 150 is connected to the electronic device 120. In this embodiment, the step (S140) of forming the inner-layer circuit 150 on the core board 102 further comprises: forming at least one blind hole 132 on the second dielectric material 130, and the blind hole 132 is connected to the electronic device 120; etching the two conductive materials 140a, 140b and forming a conductive layer 154 inside the blind hole 132, such that two inner-layer circuit patterns 152a,152b are formed by the two conductive materials 140a, 140b, and the conductive layer 154 is connected to the inner-layer circuit pattern 152b located on the second dielectric material 130 and the electronic device 120 by the blind hole 132, and the two inner-layer circuit patterns 152a,152b and the conductive layer 154 form the inner-layer circuit 150. Furthermore, in the step (S140) for forming the inner-layer circuit 150 on the core board 102 further comprises: forming at least one through hole 134 on the core board 102, and the through hole 134 penetrates the core board 102; forming the conductive layer 154 inside the through hole 134, such that the inner-layer circuit pattern 152a is electrically connected to the inner-layer circuit pattern 152b by the conductive layer 154 located inside the through hole 134.

Specifically, please refer to the FIG. 1 and FIG. 2G, in this embodiment, after the core board 102 is finished in the above-mentioned steps and the electronic device 120 is embedded in the core board 102, the blind hole 132 is formed on the second dielectric material 130 firstly, and the blind hole 132 is connected to the electronic device 120. In addition, the through hole 134 is also formed on the core board 102 in this step, and the through hole 134 penetrates the core board 102. In this embodiment, the step of forming the blind hole 132 and the through hole 134 is, for example, laser process, but it is not limited in the invention. Furthermore, in this embodiment, each of the electronic devices 120 has two electrodes 122a, 122b, and two blind holes 132 are accordingly connected to the two electrodes 122a, 122b of the electronic device 120. As a result, the inner-layer circuit 150 formed in the following step is connected to the electronic device 120 by the blind hole 132, but the number of the electrode is not limited herein and the number of that may be over two.

Next, please refer to FIG. 1 and FIG. 2H, in this embodiment, etching the two conductive materials 140a, 140b and forming the conductive layer 154 inside the blind hole 132. The step of etching the two conductive materials 140a, 140b is, for example, lithography process, so as to form two inner-layer circuit patterns 152a, 152b by etching the conductive materials 140a, 140b according to desired circuit layout. Furthermore, the step of forming the conductive layer 154 inside the blind hole 132 comprises electroplating process, in order to fill the conductive layer 154 inside the blind hole 132, and the conductive layer 154 is connected to the inner-layer circuit 152b located on the second dielectric material 130 and the electrodes 122a, 122b of the electronic device 120 through the blind hole 132. Furthermore, the conductive layer 154 in this embodiment is also formed inside the through hole 134, such that the inner-layer circuit patterns 152a, 152b formed by the conductive materials 140a, 140b above-mentioned are electrically connected to each other by the conductive layer 154 located inside the through hole 134. Therefore, the two inner-layer circuit pattern 152a, 152b and the conductive layer 154 inside the blind hole 132 and the through hole 134 form the inner-layer circuit 150, and the inner-layer circuit 150 is connected with the electronic device 120. So far, the circuit structure 100 embedded with the electronic device 120 in this embodiment has been finished, which includes the core board 102, the electronic device 120 embedded inside the core board 102 and the inner-layer circuit 150 connecting the electronic device 120. However, in addition to the inner-layer circuit 150, the circuit structure 100 embedded with the electronic device 120 in this embodiment may also dispose with additional build-up circuit 170 (shown as in FIG. 2I), so as to make the circuit structure 100 embedded with the electronic device 120 to become a multi-layer circuit structure 100.

In the step S150, forming at least one dielectric layer 160 and at least one build-up circuit 170 on the core board 102, wherein the dielectric layer 160 is located between the build-up circuit 170 and the inner-layer circuit 150, and the build-up circuit 170 is connected with the inner-layer circuit 150. Specifically, please refer to FIG. 1 and FIG. 2I, in this embodiment, the number of the dielectric layer 160 and the build-up circuit 170 is two, respectively, but it is not limited thereto. One of the dielectric layers 160 corresponds to one of the build-up circuits 170 and laminated on the first dielectric material 110. The dielectric layer 160 covers the first dielectric material 110 and the inner-layer circuit 152a located on the first dielectric material 110, and the dielectric layer 160 is located between the inner-layer circuit 150 and the corresponding build-up circuits 170. The manufacturing method of the build-up circuit 170 located on the dielectric layer 160 may be the same as that of the inner-layer circuit 150 mentioned above, for example, disposing the conductive material (not shown) on the dielectric layer 160, wherein the dielectric layer 160 and the conductive material may not only be orderly laminated on the first dielectric material 110 by different process, but also be laminated on the first dielectric material 110 by forming as a composite plate in advance during the same process. Then, a blind hole 162 is disposed on the dielectric layer 160 by laser process, a build-up circuit pattern 172 is formed by etching the conductive material during the lithography process, and a conductive layer 174 connected with the build-up circuit pattern 172 and the inner-layer circuit pattern 152a is formed inside the blind hole 162 by the electroplating process, wherein the build-up circuit pattern 172 and the conductive layer 174 form the build-up circuit 170. Similarly, the other dielectric layer 160 corresponds to the other build-up circuit 170 and laminated on the second dielectric material 130. The dielectric layer 160 covers the second dielectric material 130 and the inner-layer circuit 152b located on the second dielectric material 130, and the dielectric layer 160 is located between the inner-layer circuit 150 and the build-up circuit 170. Furthermore, the build-up circuit 170 is formed on the dielectric layer 160 by the method mentioned-above, wherein the build-up circuit pattern 172 and the conductive layer 174 of the build-up circuit 170 are connected to the inner-layer circuit pattern 152b of the inner-layer circuit 150. It can be seen that more dielectric layers 160 and more build-up circuits 170 may be disposed on the core board 102, or be disposed on the build-up circuit 170 which is already formed on the core board 102, and the build-up circuit 170 may be connected to the inner-layer circuit 150 or connected to other internal build-up circuit 170 by the method mentioned above, and part of the inner-layer circuit 150 are also connected to the electronic device 120. Therefore, the circuit structure 100 embedded with the electronic device 120 may be disposed with more dielectric layers 160 and more build-up circuit 170 according to the actual requirement, accordingly, so as to form the multi-layer circuit structure 100, and the inner-layer circuit 150 is interconnected with the build-up circuits 170.

Lastly, in the step S160, processing a surface treatment to the build-up circuit 170. Please refer to FIG. 1 and FIG. 2J, in this embodiment, after the core board 102, the inner-layer circuit 150 and the build-up circuit 170 are finished, processing the surface treatment to the build-up circuit 170. The surface treatment in this embodiment is, for example, forming a solder mask layer 180 and a plurality of soldering pads 190 on the build-up circuit 170. Because the build-up circuits 170 are disposed on the opposite sides of the circuit structure 100 embedded with the electronic device 120 in this embodiment, therefore, in this embodiment, the solder mask layers 180 are respectively formed on the two build-up circuits 170. The solder mask layers 180 cover the corresponding dielectric layers 160 and the build-up circuits 170, and expose parts of the build-up circuit patterns 172 of the build-up circuits 170 through a plurality of openings 182. After that, soldering pads 190 are disposed in the openings 182 and connected with the build-up circuit patterns 172. Accordingly, the circuit structure 100 embedded with the electronic device 120 is adapted to be electrically connected with other electronic devices (not shown) through the soldering pads 190, and other portions covered by the solder mask layer 180 are electrically insulated with other electronic devices.

To sum up, in the manufacturing method for circuit structure embedded with the electronic device of the invention, the electronic device is embedded between the first dielectric material and the second dielectric material when the second dielectric material is laminated on the first dielectric material, and the conductive materials are disposed on the first dielectric material and the second dielectric material respectively, so as to form the core board. Therefore, the electronic device is embedded inside the core board in the process of manufacturing the core board by the first dielectric material, the second dielectric material and the conductive materials, and the thin electronic device can be easily covered by the first dielectric material and the second dielectric material. Compared the method of forming the cavity on the core board for accommodating the electronic device in the related art, the manufacturing method in the invention may reduces the processing steps and the related consumptive materials what the cavity formed on the core board needed. In view of this, the manufacturing method for circuit structure embedded with the electronic device in the invention not only features in simplified process, but also reduces manufacturing cost.

Although the present invention has been described with reference to the above embodiments, it will be apparent to one of ordinary skill in the art that modifications to the described embodiments may be made without departing from the spirit of the invention. Accordingly, the scope of the invention will be defined by the attached claims and not by the above detailed descriptions.

1. A manufacturing method for a circuit structure embedded with an electronic device comprises:
providing a first dielectric material;
disposing at least one electronic device on the first dielectric material;
laminating a second dielectric material on the first dielectric material, and disposing two conductive materials on the first dielectric material and the second dielectric material respectively, such that the electronic device is embedded between the first dielectric material and the second dielectric material, wherein the first dielectric material and the second dielectric material are respectively located between the electronic device and the corresponding conductive materials, and the first dielectric material, the second dielectric material, the electronic device and the two conductive materials form a core board; and
forming an inner-layer circuit on the core board, wherein the step of forming the inner-layer circuit on the core board further comprises:
forming at least one blind hole on the second dielectric material, and the blind hole is connected to the electronic device; and
etching the two conductive materials and forming a conductive layer inside the blind hole, such that two inner-layer circuit patterns are formed by the two conductive materials, and the conductive layer is connected to the inner-layer circuit pattern located on the second dielectric material and the electronic device by the blind hole, the two inner-layer circuit patterns and the conductive layer form the inner-layer circuit, and the inner-layer circuit is connected to the electronic device.

2. The manufacturing method for the circuit structure embedded with the electronic device according to claim 1, wherein in the step of providing the first dielectric material, the first dielectric material is disposed on a bearing plate, and a release layer is disposed between the first dielectric material and the bearing plate, after the step of disposing the electronic device on the first dielectric material, the release layer and the bearing plate are removed from the first dielectric material.

3. The manufacturing method for the circuit structure embedded with the electronic device according to claim 1, further comprises:
before the step of disposing the electronic device on the first dielectric material, forming a plurality of alignment target holes on the first dielectric material.

4. The manufacturing method for the circuit structure embedded with the electronic device according to claim 1, further comprises:
before the step of disposing the electronic device on the first dielectric material, disposing at least one thermal curing glue on the first dielectric material.

5. The manufacturing method for the circuit structure embedded with the electronic device according to claim 4, wherein in the step of disposing the electronic device on the first dielectric material, the electronic device is disposed on the thermal curing glue, and the thermal curing glue is cured by a baking process, such that the electronic device is fixed on the first dielectric material.

6. (canceled)

7. The manufacturing method for the circuit structure embedded with the electronic device according to claim 6, wherein the step of forming the blind hole comprises laser process, the step of etching the two conductive materials comprises lithography process, and the step of forming the conductive layer inside the blind hole comprises an electroplating process.

8. The manufacturing method for the circuit structure embedded with the electronic device according to claim 1, further comprises:
forming at least one dielectric layer and at least one build-up circuit on the core board, wherein the dielectric layer is located between the build-up circuit and the inner-layer circuit, and the build-up circuit is connected with the inner-layer circuit.

9. The manufacturing method for the circuit structure embedded with the electronic device according to claim 8, further comprises:
processing a surface treatment to the build-up circuit.

10. The manufacturing method for the circuit structure embedded with the electronic device according to claim 1, wherein the first dielectric material and the second dielectric material comprise a prepreg doping with a glass fiber, and the two conductive materials comprises copper foil.
